(19) United States
(12) Patent Application Publication
(10) Pub. No.: US 2024/0222204 A1
(43) Pub. Date: Jul. 4, 2024

(54) SEMICONDUCTOR DEVICE

(71) Applicant: United Microelectronics Corp., Hsinchu (TW)

(72) Inventors: Yu-Yuan Huang, Hsinchu City (TW); Kai-Kuang Ho, Hsinchu City (TW); Yi-Feng Hsu, Hsinchu City (TW)

(73) Assignee: United Microelectronics Corp., Hsinchu (TW)

(21) Appl. No.: 18/163,293

(22) Filed: Feb. 2, 2023

(30) Foreign Application Priority Data
Dec. 28, 2022 (TW) 111150313

(51) Int. Cl. H01L 21/66; H01L 23/48; H01L 29/20; H01L 29/778

(52) U.S. Cl. CPC H01L 22/32; H01L 23/481; H01L 29/2003; H01L 29/7786

(57) ABSTRACT

Provided is a semiconductor device including a substrate, a semiconductor layer, a source electrode, a first metal layer, a backside via hole, and a backside metal layer. The substrate has a frontside and a backside opposite to each other. The semiconductor layer is disposed on the frontside of the substrate. The source electrode is disposed on the semiconductor layer. The first metal layer is disposed on the source electrode. The backside via hole extends from the backside of the substrate to a bottom surface of the first metal layer. The backside via hole is laterally separated from the source electrode by a non-zero distance. The backside metal layer is disposed on the backside of the substrate and extending to cover a surface of the backside via hole.

### CROSS-REFERENCE TO RELATED APPLICATION

This application claims the priority benefit of Taiwan application serial no. 111150313, filed on Dec. 28, 2022. The entirety of the above-mentioned patent application is hereby incorporated by reference herein and made a part of this specification.

### BACKGROUND OF THE INVENTION

### Field of the Invention

The present invention relates to a semiconductor device and more particularly to a high electron mobility transistor (HEMT) device and a method of forming the same.

### Description of Related Art

For semiconductor technology, it is an important development goal of semiconductor technology to continuously reduce the size of the semiconductor structures, improve the speed, increase the performance, increase the density and reduce the cost per unit circuit. However, regardless of the size of the device, its electronic characteristics must still be maintained or even improved to meet the requirements of the applied electronic products in the market. Generally speaking, unnecessary excess substances remain in each layer structure of the semiconductor device, or there is damage or poor surface properties at the formed position, which will have a non-negligible impact on the electronic characteristics of the device. Therefore, this is one of the important issues that need to be paid attention or fabricating the semiconductor devices. For example, when the chip probe (CP) testing or wire bonding is performed, the pressure of the test probes or wire bonding is likely to damage the structure under the pad, thereby affecting the yield and reliability of the device.

### SUMMARY OF THE INVENTION

The present invention provides a semiconductor device including a substrate, a semiconductor layer, a source electrode, a first metal layer, a backside via hole, and a backside metal layer. The substrate has a frontside and a backside opposite to each other. The semiconductor layer is disposed on the frontside of the substrate. The source electrode is disposed on the semiconductor layer. The first metal layer is disposed on the source electrode. The backside via hole extends from the backside of the substrate to a bottom surface of the first metal layer. The backside via hole is laterally separated from the source electrode by a non-zero distance. The backside metal layer is disposed on the backside of the substrate and extending to cover a surface of the backside via hole.

In an embodiment of the present invention, the backside via hole is physically separated from the source electrode by a dielectric material.

In an embodiment of the present invention, the backside via hole penetrates through the substrate, the semiconductor layer, and the dielectric material to contact the first metal layer.

In an embodiment of the present invention, the backside metal layer conformally covers the surface of the backside via hole to form a hollow space in the backside via hole.

In an embodiment of the present invention, the semiconductor device further includes a filling material filled into the hollow space, so that the backside metal layer wraps the filling material.

In an embodiment of the present invention, the filling material comprises an insulating material.

In an embodiment of the present invention, the filling material comprises a metal material.

In an embodiment of the present invention, the filling material and the backside metal layer have the same material.

In an embodiment of the present invention, the filling material has a bottom surface higher than a lowest bottom surface of the backside metal layer.

In an embodiment of the present invention, the filling material has a bottom surface substantially level with a lowest bottom surface of the backside metal layer.

In an embodiment of the present invention, a top view shape of the backside via hole comprises a circle, an ellipse, or a combination thereof.

In an embodiment of the present invention, a diameter of the backside via hole is between 30 μm and 60 μm, and a height of the backside via hole is between 50 μm and 200 μm.

In an embodiment of the present invention, the semiconductor device further includes: a drain electrode disposed on the semiconductor layer; and a gate electrode disposed on the semiconductor layer between the source electrode and the drain electrode, wherein the source electrode, the gate electrode, and the drain electrode are covered by a dielectric material and physically separated from each other by the dielectric material.

In an embodiment of the present invention, the semiconductor device further includes: a second metal layer disposed on the first metal layer; and an air bridge embedded between the first metal layer and the second metal layer.

In an embodiment of the present invention, the first metal layer is configured to be used as a CP test pad.

In an embodiment of the present invention, a wire bonding to a top surface of the first metal layer, wherein the backside via hole is laterally offset from the wire, so that the backside via hole does not overlap with the wire in a top view.

In an embodiment of the present invention, the source electrode completely overlaps with the first metal layer in a top view.

In an embodiment of the present invention, the source electrode does not overlap with the backside via hole in a top view.

In an embodiment of the present invention, the backside metal layer comprises a sputtered layer and an electroplating layer overlying the sputtered layer.

In an embodiment of the present invention, the semiconductor layer is a GaN epitaxial layer.

In summary, in the embodiment of the present invention, the backside conductive via is laterally separated from the source electrode by a non-zero distance, so that the backside conductive via directly contacts the bottom surface of the first metal layer (e.g., M1) and is physically separated from the source electrode. In this case, the pressure of CP test probe and/or wire bonding will not damage the backside conductive via, thereby improving device yield and reliability. In addition, in the embodiment of the present invention, the filling material (e.g., the metal material or the insulating material) may be optionally filled into the hollow space formed by the backside conductive via, so as to increase the mechanical strength of the backside conductive via and/or improve the heat dissipation performance.

To provide a further understanding of the aforementioned and other features and advantages of the disclosure, exemplary embodiments, together with the reference drawings, are described in detail below.

### BRIEF DESCRIPTION OF THE DRAWINGS

FIG. 1 is a schematic cross-sectional view of a semiconductor device according to an embodiment of the present invention.

FIG. 2 is a schematic top view of a semiconductor device according to another embodiment of the present invention.

FIG. 3 is a schematic cross-sectional view of a semiconductor device according to another embodiment of the present invention.

FIG. 4 is a schematic cross-sectional view of a semiconductor device according to alternative embodiments of the present invention.

FIG. 5 is a schematic cross-sectional view of a semiconductor device according to other embodiments of the present invention.

### DESCRIPTION OF THE EMBODIMENTS

The invention will be described in detail with reference to the drawings of the embodiments. However, the invention may also be implemented in various different forms and shall not be limited to the embodiments described herein. Thicknesses of layers and regions in the drawings are exaggerated for clarity. The same or similar numerals represent the same or similar components, which will not be repeatedly described in subsequent paragraphs.

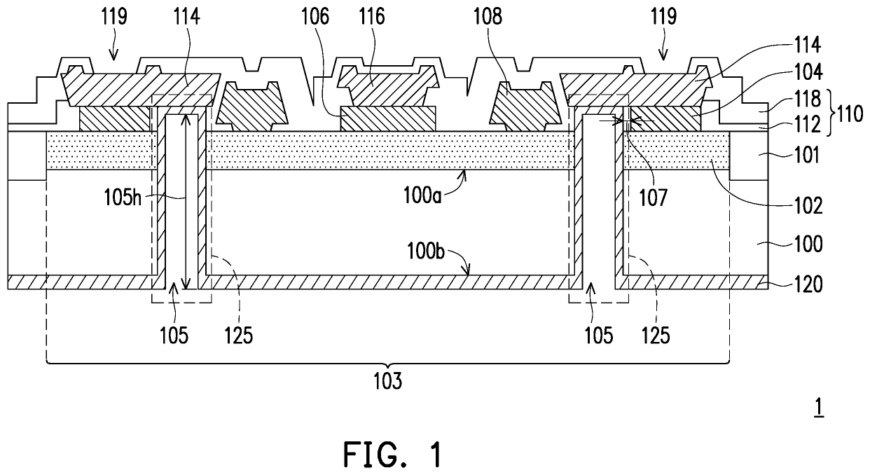

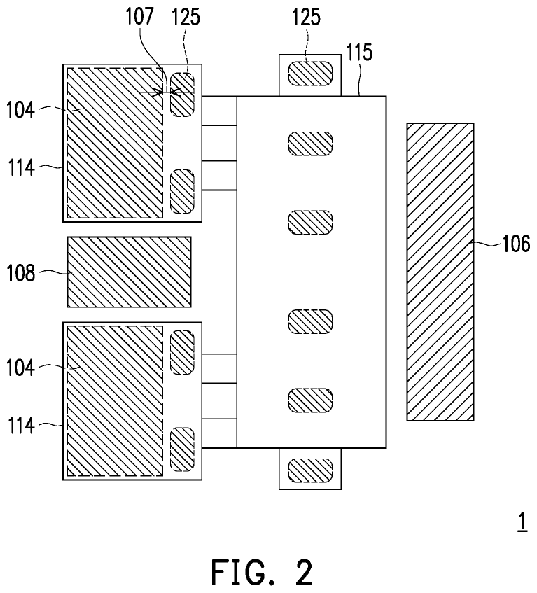

FIG. 1 is a schematic cross-sectional view of a semiconductor device according to an embodiment of the present invention. FIG. 2 is a schematic top view of a semiconductor device according to an embodiment of the present invention. The semiconductor device in the following embodiment illustrated by using a high electron mobility transistor (HEMT) device as an example, but the present invention is not limited thereto.

Referring to FIG. 1, an embodiment of the present invention provides a semiconductor device 1 including a substrate 100, a semiconductor layer 102, a source electrode 104, a drain electrode 106, a gate electrode 108, first metal layers 114, 116, and a backside metal layer 120. In detail, the substrate 100 may have a frontside 100a and a backside 100b opposite to each other. In one embodiment, the substrate 100 includes a bulk silicon substrate, a silicon carbide (SiC) substrate, a sapphire substrate, a silicon on insulator (SOI) substrate or a germanium on insulator (GOI) substrate, but the present invention is not limited thereto.

The semiconductor layer 102 may be disposed on the frontside 100a of the substrate 100. In one embodiment, the semiconductor layer 102 includes a III-V compound semiconductor, such as a gallium nitride (GaN) epitaxial layer. In one embodiment, the semiconductor layer 102 may be formed by a molecular-beam epitaxy (MBE) process, a metal organic chemical vapor deposition (MOCVD) process, a chemical vapor deposition (CVD) process, a hydride vapor phase epitaxy (HVPE) process, or the like. In addition, the semiconductor device 1 also includes an isolation structure 101 embedded in the semiconductor layer 102 and the substrate 100 to define the active area 103. In one embodiment, the isolation structure 101 may be a shallow trench isolation (STI) structure formed of silicon oxide.

The source electrode 104, drain electrode 106 and gate electrode 108 may be disposed on the semiconductor layer 102. Specifically, the source electrode 104, the drain electrode 106, and the gate electrode 108 are laterally separated from each other, and the gate electrode 108 may be disposed on the semiconductor layer 102 between the source electrode 104 and the drain electrode 106. In one embodiment, the source electrode 104, the drain electrode 106 and the gate electrode 108 all include metal materials. For example, the source electrode 104, the drain electrode 106, and the gate electrode 108 may each include metal materials such as gold, silver, platinum, titanium, aluminum, tungsten, palladium, or a combination thereof. In the present embodiment, the gate electrode 108 may be made of a Schottky metal, and the source electrode 104 and drain electrode 106 may be made of an ohmic contact metal. In some embodiments, the source electrode 104, the drain electrode 106, and the gate electrode 108 may be formed by forming electrode materials by using an electroplating process, a sputtering process, a resistance heating evaporation process, an electron beam evaporation process, a physical vapor deposition (PVD) process, a chemical vapor deposition (CVD) process, or the like, and then patterning the electrode materials.

The first metal layer 114 may be disposed on the source electrode 104 and in contact with the source electrode 104, while the first metal layer 116 may be disposed on the drain electrode 106 and in contact with the drain electrode 106. In one embodiment, both the first metal layers 114 and 116 include metal materials. For example, the first metal layers 114, 116 may each include gold, silver, platinum, titanium, aluminum, tungsten, palladium, or a combination thereof. In some embodiments, the first metal layers 114, 116 may be formed by forming metal materials by using an electroplating process, a sputtering process, a resistance heating evaporation process, an electron beam evaporation process, a physical vapor deposition (PVD) process, a chemical vapor deposition (CVD) process, or the like, and then patterning the metal materials. In the present embodiment, the first metal layers 114, 116 may be regarded as the metal one (M1).

The dielectric material 110 may wrap the source electrode 104, the drain electrode 106, the gate electrode 108, and the first metal layers 114, 116, so that the source electrode 104, the drain electrode 106, the gate electrode 108, and the first metal layers 114, 116 are physically separated from each other by the dielectric material 110. In one embodiment, the dielectric material 110 includes a first dielectric layer 112 and a second dielectric layer 118 disposed on the first dielectric layer 112. The first dielectric layer 112 and the second dielectric layer 118 may include different materials. For example, the first dielectric layer 112 may be a silicon nitride layer, while the second dielectric layer 118 may be a silicon oxide layer. However, the present invention is not limited thereto, in other embodiments, the first dielectric layer 112 and the second dielectric layer 118 may also include the same material, such as silicon oxide.

In addition, the semiconductor device 1 also includes a backside via hole 105. The backside via hole 105 may extend from the backside 100b of the substrate 100 to the bottom surface of the first metal layer 114, and the backside via hole 105 is laterally separated from the source electrode 104 by a non-zero distance 107. Herein, the non-zero distance 107 may be adjusted according to product requirements, as long as the backside via hole 105 may be physically separated from the source electrode 104 by the dielectric material 110, it is within the protection scope of the present invention. Specifically, the backside via hole 105 may penetrate through the substrate 100, the semiconductor layer 102, and the dielectric material 110 to contact the first metal layer 114. In one embodiment, a height 105h of the backside via hole 105 is between 50 μm and 200 μm.

In addition, the backside metal layer 120 may be disposed on the backside 100b of the substrate 100 and extend to cover the surface of the backside via hole 105. In one embodiment, the backside metal layer 120 may conformally cover the surface of the backside via hole 105 to form a hollow space in the backside via hole 105. In this case, a portion of the backside metal layer 120 that conformally covers the surface of the backside via hole 105 may be referred to as a backside conductive via 125. The backside conductive via 125 may electrically connect the first metal layer 114 and the backside metal layer 120, so as to transmit the electrical signal of the source electrode 104 on the frontside 100a of the substrate 100 to the backside 100b of the substrate 100 through the backside conductive via 125, so that the metal routing is more flexible. It should be noted that, in the present embodiment, the backside conductive via 125 is laterally separated from the source electrode 104 by the non-zero distance 107, so that the backside conductive via 125 is in direct contact with the bottom surface of the first metal layer 114 and is physically separated from the source electrode 104. In this case, the first metal layer 114 may be configured to use as a chip probe (CP) test pad or as a wire bonding pad. That is, when the CP test probe and/or the wire bonding is applied on the first metal layer 114 through the opening 119, the CP test probe and/or the wire bonding will land on the first metal layer 114 directly above the source electrode 104. Therefore, the pressure of the CP test probe and/or wire bonding will not fall on the first metal layer 114 directly above the backside conductive via 125, so as to protect the backside conductive via 125 from damage, thereby improving the yield and the reliability of the semiconductor device 1. In one embodiment, the backside metal layer 120 includes a metal material, such as gold, silver, platinum, titanium, aluminum, tungsten, palladium, or a combination thereof. In some embodiments, the backside metal layer 120 may be formed by using an electroplating process, a sputtering process, a resistance heating evaporation process, an electron beam evaporation process, a physical vapor deposition (PVD) process, a chemical vapor deposition (CVD) process, or the like. For example, the backside metal layer 120 may include a sputtered layer and an electroplating layer overlying the sputtered layer. In one embodiment, a thickness of the backside metal layer 120 is between 4 μm and 6 μm.

From a top view of FIG. 2, the semiconductor device 1 may include a plurality of backside conductive vias 125. Specifically, a portion of the backside conductive via 125 may be laterally separated from the source electrode 104 by the non-zero distance 107 and may be in direct contact with the bottom surface of the first metal layer 114. In one embodiment, the source electrode 104 completely overlaps with the first metal layer 114 in the top view, while the source electrode 104 does not overlap with the backside conductive via 125 (or the backside via hole 105) in the top view. That is, when the wire bonding is bonded to the top surface of the first metal layer 114, the backside conductive via 125 is laterally offset from the bonding wire, so that the backside conductive via 125 does not overlap with the bonding wire in the top view, thereby preventing the backside conductive via 125 from damage. Another portion of the backside conductive vias 125 may be disposed at the metal one (M1) of the interconnect structure 115 to make the metal routing more flexible. Although the top view shape of the backside conductive vias 125 (or the backside via holes 105) illustrated in FIG. 2 is an ellipse, the present invention is not limited thereto. In other embodiments, the top view shape of the backside conductive vias 125 (or the backside via holes 105) may also be a circle or a combination of a circle and an ellipse. Taking a circle as an example, the diameter of the backside conductive via 125 is between 30 μm and 60 μm. Taking an ellipse as an example, a length of the major axis and a length of the minor axis of the backside conductive via 125 may be 60 μm and 30 μm, but the present invention is not limited thereto.

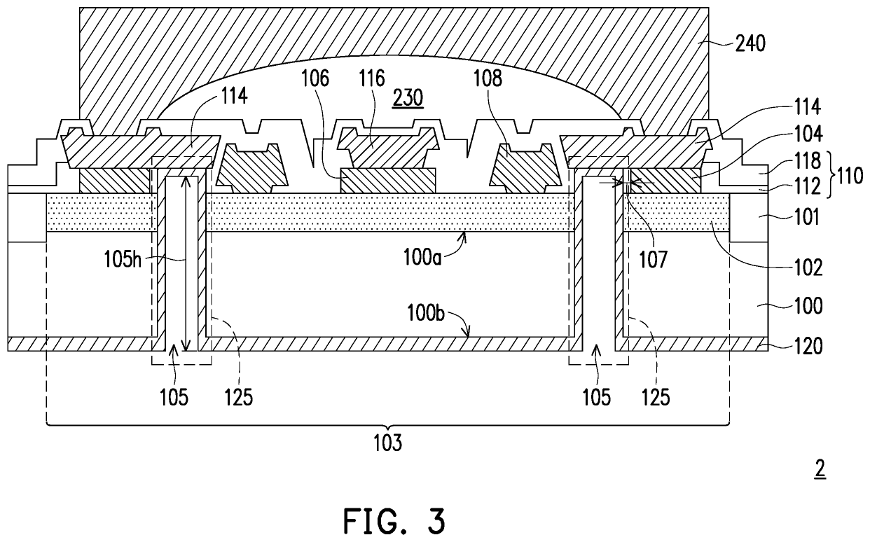

FIG. 3 is a schematic cross-sectional view of a semiconductor device according to another embodiment of the present invention.

A semiconductor device 2 of FIG. 3 is similar to the semiconductor device 1 of FIG. 1, the similar components and configurations have been described in detail in the above paragraphs, and thus the details are omitted herein. The main difference between the semiconductor device 2 and the semiconductor device 1 lies in that the semiconductor device 2 further includes a second metal layer 240 and an air bridge 230. Specifically, the second metal layer 240 may be disposed on the first metal layer 114 and in contact with the first metal layer 114. In one embodiment, one end of the second metal layer 240 is connected to one first metal layer 114, and the other end of the second metal layer 240 is connected to the adjacent first metal layer 114, thereby forming the air bridge 230. In the present embodiment, the air bridge 230 is filled with the air with a dielectric constant close to 1, which can effectively reduce the capacitance of the interconnect structure and reduce the resistance-capacitance (RC) delay, thereby improving the operating efficiency of the device. The air bridge 230 may be defined by the first metal layer 114 and the second metal layer 240. That is, the air bridge 230 may be embedded between the first metal layer 114 and the second metal layer 240.

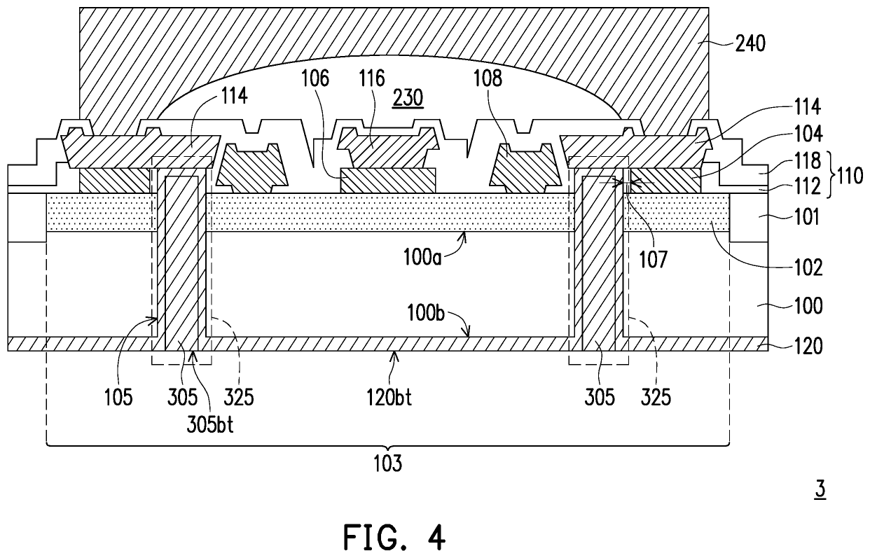

FIG. 4 is a schematic cross-sectional view of a semiconductor device according to alternative embodiments of the present invention.

A semiconductor device 3 of FIG. 4 is similar to the semiconductor device 2 of FIG. 3, the similar components and configurations have been described in detail in the above paragraphs, and thus the details are omitted herein. The main difference between the semiconductor device 3 and the semiconductor device 2 lies in that the semiconductor device 3 further includes a filling material 305. Since the backside metal layer 120 conformally covers the surface of the backside via hole 105, a hollow space may be formed in the backside via hole 105. The filling material 305 may be filled into the hollow space, so that the backside metal layer 120 wraps the filling material 305. In one embodiment, the backside metal layer 120 and the filling material 305 have the same material, such as a metal material. In this case, a portion of the backside metal layer 120 that conformally covers the surface of the backside via hole 105 and the fill material 305 may be referred to as a backside conductive via 325. The backside conductive via 325 may electrically connect the first metal layer 114 and the backside metal layer 120, so as to transmit the electrical signal of the source electrode 104 on the frontside 100a of the substrate 100 to the backside 100b of the substrate 100 through the backside conductive via 325, so that the metal routing is more flexible. It should be noted that, in the present embodiment, the backside conductive via 325 made of a solid structure can not only reduce the impedance of the backside conductive via 325, but also improve the mechanical strength and the heat dissipation performance of the backside conductive via 325. In addition, a bottom surface 305bt of the filling material 305 may be substantially level with a lowest bottom surface 120bt of the backside metal layer 120, so as to facilitate subsequent connection with external components. However, the present invention is not limited thereto, in other embodiments, the bottom surface 305bt of the filling material 305 may also be higher than the lowest bottom surface 120bt of the backside metal layer 120.

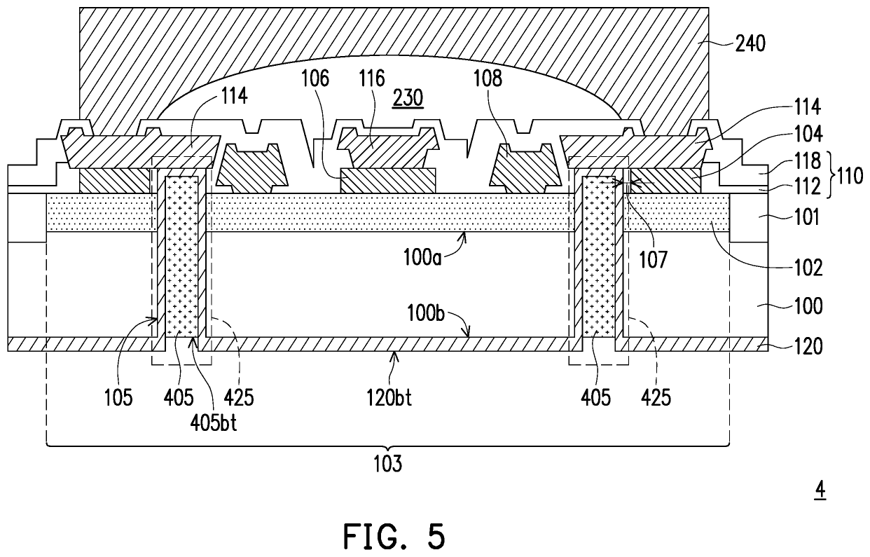

FIG. 5 is a schematic cross-sectional view of a semiconductor device according to other embodiments of the present invention.

A semiconductor device 4 of FIG. 5 is similar to the semiconductor device 3 of FIG. 4, the similar components and configurations have been described in detail in the above paragraphs, and thus the details are omitted herein. The main difference between the semiconductor device 4 and the semiconductor device 3 lies in that a filling material 405 of the semiconductor device 4 and the backside metal layer 120 have different materials. Specifically, the backside metal layer 120 is a metal material, and the filling material 405 is an insulating material, such as silicon nitride. In this case, a portion of the backside metal layer 120 that conformally covers the surface of the backside via hole 105 and the filling material 405 may be referred to as a backside conductive via 425. It should be noted that, in the present embodiment, the filling material 405 made of the insulating material can increase the mechanical strength of the backside conductive via 425. In addition, a bottom surface 405bt of the filling material 405 may be higher than the lowest bottom surface 120bt of the backside metal layer 120. However, the present invention is not limited thereto, in other embodiments, the bottom surface 405bt of the filling material 405 may also be substantially level with the lowest bottom surface 120bt of the backside metal layer 120.

In summary, in the embodiment of the present invention, the backside conductive via is laterally separated from the source electrode by a non-zero distance, so that the backside conductive via directly contacts the bottom surface of the first metal layer (e.g., M1) and is physically separated from the source electrode. In this case, the pressure of CP test probe and/or wire bonding will not damage the backside conductive via, thereby improving device yield and reliability. In addition, in the embodiment of the present invention, the filling material (e.g., the metal material or the insulating material) may be optionally filled into the hollow space formed by the backside conductive via, so as to increase the mechanical strength of the backside conductive via and/or improve the heat dissipation performance.

Although the invention is disclosed as the embodiments above, the embodiments are not meant to limit the invention. Any person skilled in the art may make slight modifications and variations without departing from the spirit and scope of the invention. Therefore, the protection scope of the invention shall be defined by the claims attached below.

What is claimed is:

1. A semiconductor device, comprising:
a substrate having a frontside and a backside opposite to each other;
a semiconductor layer disposed on the frontside of the substrate;
a source electrode disposed on the semiconductor layer;
a first metal layer disposed on the source electrode;
a backside via hole extending from the backside of the substrate to a bottom surface of the first metal layer, wherein the backside via hole is laterally separated from the source electrode by a non-zero distance; and
a backside metal layer disposed on the backside of the substrate and extending to cover a surface of the backside via hole.

2. The semiconductor device of claim 1, wherein the backside via hole is physically separated from the source electrode by a dielectric material.

3. The semiconductor device of claim 2, wherein the backside via hole penetrates through the substrate, the semiconductor layer, and the dielectric material to contact the first metal layer.

4. The semiconductor device of claim 1, wherein the backside metal layer conformally covers the surface of the backside via hole to form a hollow space in the backside via hole.

5. The semiconductor device of claim 4, further comprising: a filling material filled into the hollow space, so that the backside metal layer wraps the filling material.

6. The semiconductor device of claim 5, wherein the filling material comprises an insulating material.

7. The semiconductor device of claim 5, wherein the filling material comprises a metal material.

8. The semiconductor device of claim 5, wherein the filling material and the backside metal layer have the same material.

9. The semiconductor device of claim 5, wherein the filling material has a bottom surface higher than a lowest bottom surface of the backside metal layer.

10. The semiconductor device of claim 5, wherein the filling material has a bottom surface substantially level with a lowest bottom surface of the backside metal layer.

11. The semiconductor device of claim 1, wherein a top view shape of the backside via hole comprises a circle, an ellipse, or a combination thereof.

12. The semiconductor device of claim 1, wherein a diameter of the backside via hole is between 30 μm and 60 μm, and a height of the backside via hole is between 50 μm and 200 μm.

13. The semiconductor device of claim 1, further comprising:
a drain electrode disposed on the semiconductor layer; and
a gate electrode disposed on the semiconductor layer between the source electrode and the drain electrode, wherein the source electrode, the gate electrode, and the drain electrode are covered by a dielectric material and physically separated from each other by the dielectric material.

14. The semiconductor device of claim 1, further comprising:
a second metal layer disposed on the first metal layer; and
an air bridge embedded between the first metal layer and the second metal layer.

15. The semiconductor device of claim 1, wherein the first metal layer is configured to be used as a chip probe (CP) test pad.

16. The semiconductor device of claim 1, further comprising: a wire bonding to a top surface of the first metal layer, wherein the backside via hole is laterally offset from the wire, so that the backside via hole does not overlap with the wire in a top view.

17. The semiconductor device of claim 1, wherein the source electrode completely overlaps with the first metal layer in a top view.

18. The semiconductor device of claim 1, wherein the source electrode does not overlap with the backside via hole in a top view.

19. The semiconductor device of claim 1, wherein the backside metal layer comprises a sputtered layer and an electroplating layer overlying the sputtered layer.

20. The semiconductor device of claim 1, wherein the semiconductor layer is a GaN epitaxial layer.
